(19) United States
(12) Patent Application Publication
(10) Pub. No.: US 2010/0141260 A1
(43) Pub. Date: Jun. 10, 2010

(54) RF Coils for Magnetic Resonance Tomography

(75) Inventor: Harry Schilling, Eichstaett (DE)

Correspondence Address: DAFFER MCDANIEL LLP, P.O. BOX 684908, AUSTIN, TX, 78768, US

(73) Assignee: SCHLEIFRING UND APPARATEBAU GMBH, Fuerstenfeldbruck (DE)

(21) Appl. No.: 12/328,897

(22) Filed: Dec. 5, 2008

(51) Int. Cl. G01R 33/32

(52) U.S. Cl. 324/322

(57) ABSTRACT

A transmitting or receiving coil assembly for magnetic resonance tomographs comprising at least one flexible printed circuit board having inductors and at least one bar attached thereto for stiffening the flexible printed circuit board along one axis. The bar optionally has conductors for connecting electronic components on the printed circuit board with each other or with outside components of the magnetic resonance tomograph.

### BACKGROUND OF THE INVENTION

1. Field of the Invention

The invention relates to magnetic resonance tomography and, in particular, to medical instruments for examining human and animal bodies. Magnetic resonance tomography (MRT) is also known as nuclear spin tomography.

2. Description of the Prior Art

MRT is an image-generating method based on the physical phenomenon of nuclear spin resonance. An object to be examined is subjected to a strong magnetic field. This causes an alignment of previously statistically distributed nuclear spins of the individual atoms. Excitement with high-frequency energy from outside causes measurable oscillations. The frequency is a function of the magnetic field strength. For spatial localization, magnetic fields which are inhomogeneous along the three spatial axes are generated using gradient coils. Transmitting coils are provided for emitting the high-frequency excitation energy. A reception of excited oscillations is effected with receiving coils. Transmitting coils and receiving coils are frequently combined with each other. In the following, these coils are also referred to as HF coils, because they serve for coupling-in or coupling-out high-frequency signals.

This non-invasive image-generating method makes it possible to obtain images of sections through a human or animal body along any desired axes.

Examples of transmitting and receiving coils are disclosed in U.S. Pat. No. 4,887,039. There pluralities of parallel conductors which are connected to each other via coupling capacitors are mounted on a cylindrical support. Feeding is effected by means of symmetrical conductors or coaxial cables. So-called phased-array arrangements are employed in order to achieve higher resolutions. For this, pluralities of independent coils having independent receiver inputs are connected for separate evaluation of the signals.

The construction of coils of this kind is very complex and the manufacturing costs are therefore relatively high. In coil arrangements of the future, an increasing number of coils will have to be provided, whilst the higher resolution will cause even greater demands to be made on the mechanical tolerances.

### BRIEF SUMMARY OF THE INVENTION

The problems outlined above may be in large part addressed by a high-frequency (HF) coil assembly having a simplified mechanical construction, whilst maintaining or improving electrical properties and mechanical stability. In addition, reduced mechanical tolerances and manufacturing costs are realized with such a coil assembly. The following are mere exemplary embodiments of a coil assembly and a magnetic resonance imaging device employing such characteristics and are not to be construed in any way to limit the subject matter of the claims.

An embodiment of a high-frequency (HF) coil assembly for magnetic resonance tomographs includes at least one flexible printed circuit board having inductors and at least one bar attached thereto for stiffening the flexible printed circuit board along one axis. The bar optionally has conductors for connecting electronic components on the printed circuit board with each other or with outside components of the magnetic resonance tomograph. An embodiment of a magnetic resonance imaging device includes at least one of such HF coil assemblies.

### BRIEF DESCRIPTION OF THE DRAWINGS

In the following, the invention will be described by way of example on embodiments with reference to the drawings without limitation of the general inventive concept.

FIG. 1 schematically shows in a general form a magnetic resonance tomography scanner;

FIG. 2 shows a top view of a coil assembly according to the invention;

FIG. 3 shows a view towards one end of the coil embodiment of FIG. 2;

FIG. 4 shows an embodiment with L-shaped bars;

FIG. 5 shows a side view of a bar;

FIG. 6 shows cross-sectional views of strip lines; and

FIG. 7 shows a coil bent to a cylindrical form.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION

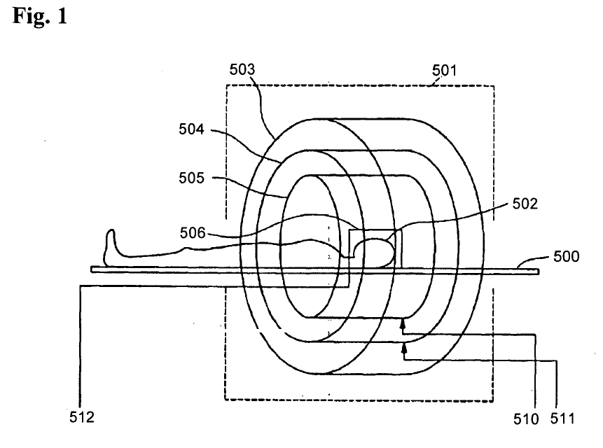

FIG. 1 schematically shows in a general form a device for magnetic resonance tomography. A patient 502 lies on a berth 500 in a magnet system 501. Animals or any desired objects also may be examined instead of a patient. A main magnet 503 serves to generate a static main magnetic field. For determination of location, temporally and spatially variable magnetic fields are generated by means of gradient coils 504. These are controlled by gradient signals 511. A high-frequency field for exciting magnetic resonance resonances is fed into an object to be examined with the aid of a transmitted signal 510 through transmitting coils 505. Detection of measurement signals 512 is effected by means of receiving coils 506. Optionally, the transmitting coils and the receiving coils may be spatially combined with each other. Similarly, the same coil assembly may first be used for signal emission and later for signal reception. The receiving coils 506 may also be in an outer region of the transmitting coils 505. Similarly, the transmitting coils 505 also may be disposed in the vicinity of the object to be examined, in the same way as the receiving coils 506 shown here.

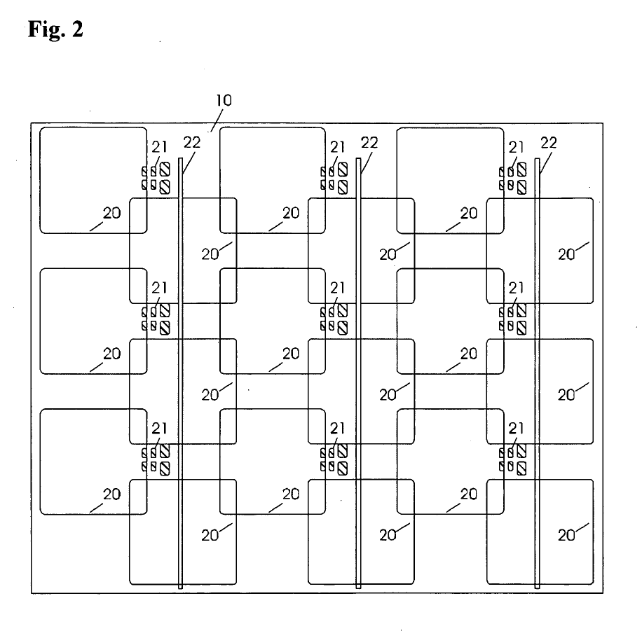

FIG. 2 shows a view of a coil assembly in accordance with the systems described herein. A plurality of coils 20 are arranged on a printed circuit board 10. In some cases, this insulator is a flexible printed circuit board. In addition to the coils 20, electronic components 21 are provided. Such electronic components may be capacitors for tuning the resonance frequency of the coils, diodes for switching, amplifiers, or any other kind of electronic devices. Bars 22 are attached to the printed circuit board 10, such as at a 90° angle. These bars may include printed circuit boards. They carry conductors for connecting the coils 20 and/or the electronic components 21 to other parts of the magnetic resonance scanner. Furthermore, these bars may be of a rigid type printed circuit board to stiffen the printed circuit board 10 in one axis along the bars. In some cases, the printed circuit board may be bent along an axis at an angle, such as a right angle, to the bars. In some embodiments, all components on the printed circuit board 10, except the bars 22, are arranged at the same level, so the components can be assembled by an automatic pick and place machine.

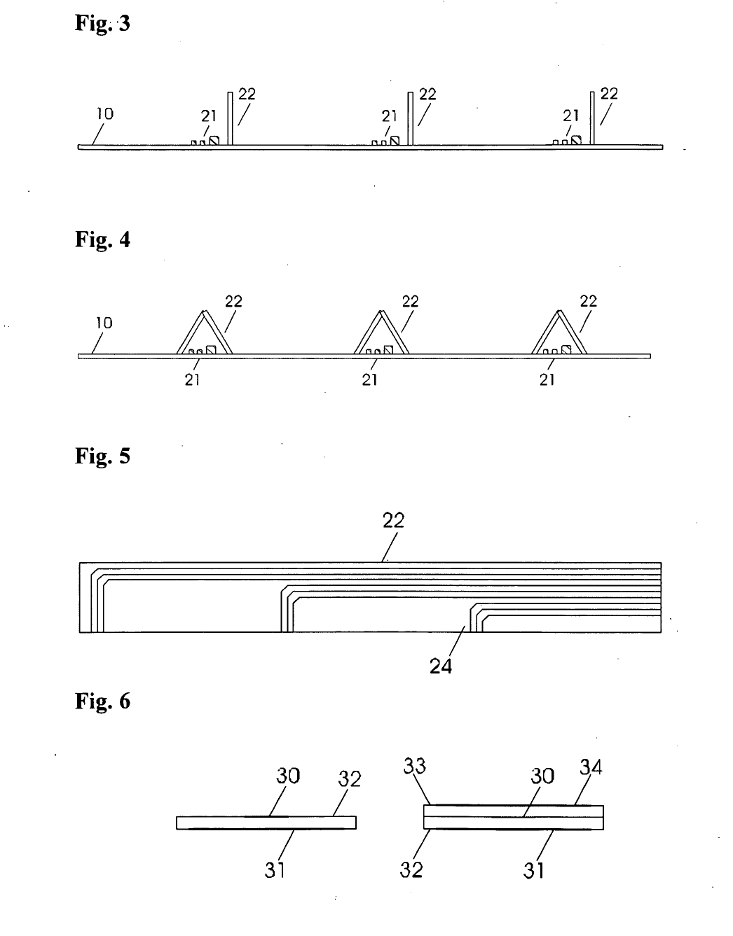

FIG. 3 shows a view at one end of a coil embodiment, specifically a view into the bottom side of FIG. 2. In this example, the bars 22 are arranged at a right angle relative to the printed circuit board 10. Larger or smaller angles may be realized.

FIG. 4 shows another view at one end of another embodiment of a coil assembly. Here, the bars 22 comprise two pieces of printed circuit board material, roughly forming an L-shape, which is attached to the printed circuit board 10. In this specific example, they form an equilateral triangle, although other assemblies are possible.

FIG. 5 shows a side view of a bar 22. The bar has conductors 24 for connecting the coils 20 and/or the electronic components 21. In this specific example, three groups of three conductors each end at the bottom side of the bar and are connected to the printed circuit board 10. Connection may be done by soldering. The conductors lead to the right side of the bar, where it can be connected, for example, by connectors or cables to the rest of the magnetic resonance imaging device.

FIG. 6 shows cross-sectional views of embodiments of the conductors 20 as strip lines. The left most drawing in FIG. 6 depicts a simple strip line. It comprises an electrical conductor 30 for guiding the signal and a ground plane 31 isolated by the isolator 32, which is usually part of the printed circuit board. The right most drawing in FIG. 6 depicts a sandwich strip line. The electrical conductor 30 for the signal is embedded between ground planes 31 and 34. Both ground planes are connected with each other. The conductor 30 is isolated against the ground planes by the isolators 32 and 33.

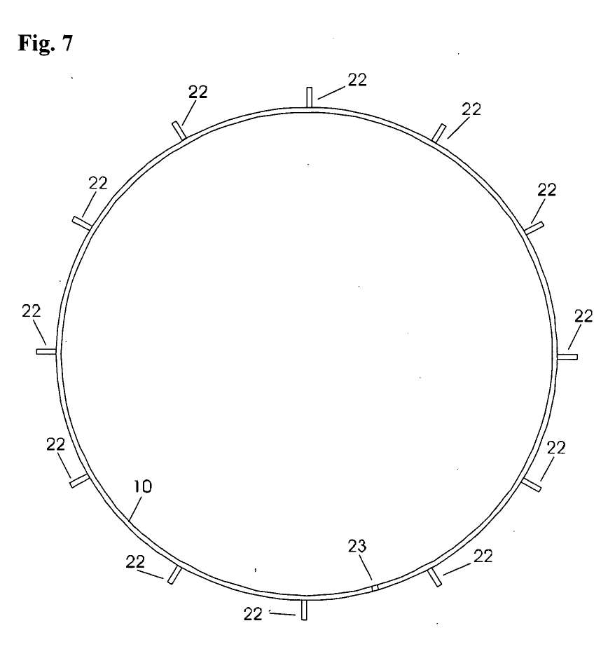

FIG. 7 shows an embodiment of a coil assembly bent to a cylindrical form in a top view. This may be the result of bending a larger piece of a device according to FIG. 2 around a vertical axis. The left side and the right side of the printed circuit board 10 shown in FIG. 7 are connected together at the gap 23.

The coil assemblies described herein include a printed circuit board 10. In some cases, the printed circuit board 10 may be of a multi-layer construction, in which at least two layers are joined together, such as in the form of a laminate. At least one layer comprises a dielectric insulating material (insulator layer) having as low as possible dielectric losses in the operating frequency range of the coil assembly. Materials of this kind may comprise, for example, plastics such as PTFE (polytetrafluoroethylene), PE (polyethylene), or also ceramic materials. In order to increase the mechanical stability, fibers such as glass fibers or carbon fibers may be embedded.

A typical operating frequency range of the coil assemblies described herein is in the range of about 30 MHz to about several 100 MHz according to the prevailing outer magnetic field of the assembly. Firmly connected to the insulating material is at least one layer of conducting material (conductor layer), the shape of the coils having been formed in this layer. A connection between the layers, or the layers themselves, may be semi-flexible, so that internal mechanical tension cannot be caused, or can be reduced, when the assembly is subjected to bending. A conducting layer may be applied onto the first layer, optionally by chemical or electrochemical methods, in particular by electroplating or etching, or mechanically. Thus, it may be rolled on, for example in the form of a thin foil.

The flexible printed circuit board 10 carries besides the inductors at least one other electronic component, preferably a discrete component, which optionally comprises coils, resistors, and also semiconductors such as, for example, diodes. A discrete component is an electronic component which is not integrated into the printed circuit board and is self contained in its own housing. It can be soldered to the printed circuit board. Examples of discrete electronic components are SMD (surface mount devices) or wired capacitors, inductors, resistors and semiconductors. These components may be made by SMD technology in order to enable particularly space saving and efficient assembly.

Furthermore, at least one of bar 22 is attached to the printed circuit board. The bar may be laminated, glued, soldered or welded to flexible printed circuit board 10. In some cases, it is attached on a significant part of its length, and in further cases on its whole length. Alternatively, there may be gaps in the bar, for example at positions, where an electronic component is located under the bar. In some embodiments, the bar is stiff compared to the printed circuit board 10. Accordingly, the bar may include a thicker material. It may be arranged at right angle to the printed circuit board, but other angles may be employed. It stiffens the flexible printed circuit board in one axis parallel to the bar. The flexible printed circuit board may still be bent at right angle to the bar. The bar may be a printed circuit board which has conductors to connect components on the printed circuit board like inductors 20 and/or electronic components 21 with each other and/or with other parts of the magnetic resonance imaging device. The bar may serve for connecting parts on the printed circuit board to the outside. The connecting lines on the printed circuit bar of the coils have negative effects on the coils and, thus, the connecting lines are separated from the coils and have much less influence on the coils. Therefore, a low interaction with the coil can be achieved. In some cases, a plurality of bars is provided parallel at equal distances.

In further embodiments, the bar 22 comprises at least one strip line. Strip lines are electrical lines on printed circuit boards having specific characteristic impedance, such as 50 Ohms or 100 Ohms. Close to a strip line is at least one ground layer. Accordingly, the bar 22 may comprise at least one ground layer, and on top of this isolated by an insulating layer an electrical line. Alternatively, the electrical line may be sandwiched in between two ground layers which are connected together. All coils of the known prior art suffer from the problem, that it is difficult to transfer signals from the coils to other parts of the scanner.

In other embodiments, the bars are L-shaped or U-shaped. This results in a further increasing of stability. These bars form a triangle or a square in conjunction with the flexible printed circuit board 10.

In further embodiments, the printed circuit board is bent to a cylindrical form.

According to further embodiments second bars are provided, which are attached to the flexible printed circuit 10 at an angle to the first bars 22 to stiffen the flexible printed circuit board in a second axis, making it stable in two dimensions.

In other embodiments, reinforcement members are additionally provided on the flexible printed circuit board 10 to further increase the mechanical stability of the entire assembly. Particularly important are the locations on the assembly at which recesses have been provided, or at which various parts of printed circuit boards, or layers of insulating material, have been joined together. It is here that cracks or breaks predominantly form when mechanical stresses act on the entire assembly. The reinforcement members are provided additionally in order to avoid these.

It is of particular advantage for the reinforcement members to comprise a plastic material. Particularly expedient is the use of fiber-reinforced (glass fiber, carbon fiber, etc.) plastics.

Furthermore, it is of advantage for at least one of the reinforcement members to be incorporated into the assembly itself, preferably by pressing or casting.

It will be appreciated to those skilled in the art having the benefit of this disclosure that this invention is believed to provide an HF coil assembly for magnetic resonance imaging. Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A high-frequency (HF) coil assembly for magnetic resonance tomographs, comprising:
at least one flexible printed circuit board carrying inductors and at least one other electronic component; and
at least one bar of a non-flexible printed circuit board attached at an angle to the printed circuit board, the bar having conductors connected to said flexible printed circuit board for electrically connecting components on the flexible printed circuit board with each other or with other components of the magnetic resonance tomograph located outside of the flexible printed circuit board.

2. The HF coil assembly according to claim 1, wherein said angle is a right angle.

3. The HF coil assembly according to claim 1, wherein said bars are L-shaped.

4. The HF coil assembly according to claim 1, wherein said bars are U-shaped.

5. The HF coil assembly according to claim 1, wherein said conductors comprise strip lines.

6. The HF coil assembly according to claim 1, wherein the flexible printed circuit board is cylindrical.

7. The HF coil assembly according to claim 1, wherein the at least one bar comprises a plurality of bars arranged equal distances relative to each other.

8. A magnetic resonance imaging (MRI) device comprising at least one high-frequency (HF) coil assembly, wherein the at least one HF coil comprises:
at least one flexible printed circuit board carrying inductors and at least one other electronic component; and
at least one bar of a non-flexible printed circuit board attached at an angle to the printed circuit board, the bar having conductors connected to said flexible printed circuit board for electrically connecting components on the flexible printed circuit board with each other or with other components of the magnetic resonance tomograph located outside of the flexible printed circuit board.

9. The MRI device according to claim 1, wherein said angle is a right angle.

10. The MRI device according to claim 1, wherein said bars are L-shaped.

11. The MRI device according to claim 1, wherein said bars are U-shaped.

12. The MRI device according to claim 1, wherein said conductors comprise strip lines.

13. The MRI device according to claim 1, wherein the flexible printed circuit board is cylindrical.

14. The MRI device according to claim 1, wherein the at least one bar comprises a plurality of bars arranged equal distances relative to each other.
